(19) United States
(12) Patent Application Publication
(10) Pub. No.: US 2022/0013696 A1
(43) Pub. Date: Jan. 13, 2022

(54) Electronic Device and Manufacturing Method thereof

(71) Applicant: SHENZHEN ROYOLE TECHNOLOGIES CO., LTD., Shenzhen (CN)

(72) Inventors: Jiahao KANG, Shenzhen (CN); Ze YUAN, Shenzhen (CN); Haojun LUO, Shenzhen (CN); Wenbing HU, Shenzhen (CN); Shaowen WANG, Shenzhen (CN)

(21) Appl. No.: 17/369,282

(22) Filed: Jul. 7, 2021

(30) Foreign Application Priority Data
Jul. 7, 2020 (CN) 202010647731.0

(51) Int. Cl. H01L 33/48; H01L 33/62; H01L 27/15; H01L 33/00

(52) U.S. Cl. CPC H01L 33/486; H01L 33/62; H01L 2933/0066; H01L 33/005; H01L 27/156

(57) ABSTRACT

The present disclosure discloses an electronic device, including backplane circuits, a plurality of conductive adhesive elements arranged on the backplane circuits at intervals, and a plurality of electronic components arranged on the plurality of conductive adhesive elements respectively. The backplane circuits are respectively electrically connected with the plurality of electronic components through the plurality of conductive adhesive elements. The present disclosure further discloses a manufacturing method used for manufacturing the above electronic device.

### TECHNICAL FIELD

The present disclosure relates to the technical field of display, and more particularly relates to an electronic device and a manufacturing method thereof.

### BACKGROUND ART

With continuous development of flexible electronics, due to advantages such as light weight, small thickness and flexibility, a flexible electronic device becomes a new-generation electronic technique.

At present, most of mainstream flexible electronic devices are as follows: conductive adhesive element is formed on the whole surface of a flexible substrate provided with a backplane circuits so as to connect electronic components. However, since the conductive adhesive element on the whole surface has high rigidity and brittleness after curing, the conductive adhesive element on the whole surface cannot be stretched when the flexible electronic device deforms; and thus, deformation performance of the whole electronic device is lowered.

### SUMMARY OF THE INVENTION

With respect to problems existing in the related art, one embodiment of the present disclosure provides an electronic device and a manufacturing method thereof, for solving a problem that an existing electronic device is low in deformation performance.

In the first aspect, embodiments of the present disclosure provide an electronic device. The electronic device includes a plurality of backplane circuits, a plurality of conductive adhesive elements arranged on the backplane circuits at intervals, respectively; and a plurality of electronic components arranged on the plurality of conductive adhesive elements respectively. The backplane circuits are respectively electrically connected with the plurality of electronic components through the plurality of conductive adhesive elements.

In one embodiment, the backplane circuits are flexible; and the electronic components are rigid.

In one embodiment, the electronic device further includes an electrical connector arranged on each of the backplane circuits and/or the electronic components; the conductive adhesive elements are anisotropic conductive materials; and the conductive adhesive elements are pressed by the electrical connector to realize vertical conduction and horizontal insulation between the backplane circuits and the electronic components.

In one embodiment, the electrical connector includes a first terminal and a second terminal arranged on each electronic component; and the first terminal and the second terminal protrude out of the electronic component and face a corresponding conductive adhesive element.

In one embodiment, the electrical connector includes a third terminal and a fourth terminal arranged on each of the backplane circuits; and the third terminal and the fourth terminal protrude out of the backplane circuit and face a corresponding conductive adhesive element.

In one embodiment, the electrical connector includes a first terminal and a second terminal arranged on each of the electronic components, and a third terminal and a fourth terminal arranged on each of the backplane circuits;

the first terminal and the second terminal protrude out of the electronic component and face a corresponding conductive adhesive element; the third terminal and the fourth terminal protrude out of the backplane circuit and face a corresponding conductive adhesive element; and

the first terminal and the third terminal are arranged opposite to each other and press a corresponding conductive adhesive element together so as to realize electrical connection between the backplane circuit and the electronic component; and the second terminal and the fourth terminal are arranged opposite to each other and press a corresponding conductive adhesive element together so as to realize electrical connection between the backplane circuit and the electronic component.

In one embodiment, the electronic device further includes a flexible substrate arranged on one side of the backplane circuits away from the conductive adhesive elements.

In one embodiment, the flexible substrate includes a plurality of island substrates arranged at intervals and a plurality of connecting substrates used for connecting two adjacent island substrates; the backplane circuits include a plurality of island circuits arranged at intervals and a plurality of connecting wires used for electrically connecting two adjacent island circuits; the island substrates, the island circuits, the conductive adhesive elements and the electronic components are stacked; and the plurality of connecting wires are respectively arranged on the plurality of connecting substrates.

In one embodiment, each of the electronic components include one or a plurality of Micro-LEDs; the first terminal and the second terminal are respectively a cathode and an anode of the Micro-LED; the backplane circuits are TFT circuits; and the TFT circuits are electrically connected with the Micro-LEDs and drive the Micro-LEDs through the third terminals and the fourth terminals.

In one embodiment, the electronic device further includes an upper elastic packaging layer enclosing the electronic components and/or a lower elastic packaging layer arranged on the lower side of the flexible substrate.

In the second aspect, embodiments of the present disclosure provide a manufacturing method of an electronic device. The manufacturing method includes the following steps: forming a plurality of backplane circuits on a flexible substrate, wherein the backplane circuits have a plurality of connecting ends formed thereon respectively; forming conductive adhesive elements arranged at intervals on the backplane circuits, respectively; wherein the conductive adhesive elements are anisotropic conductive materials; and arranging electronic components on the conductive adhesive elements, respectively, wherein the electronic components have a plurality of conductive ends formed thereon respectively; and the conductive ends and the connecting ends are arranged opposite to each other and press the conductive adhesive elements together so as to realize electrical connection between the backplane circuits and the electronic components.

In one embodiment, the forming conductive adhesive elements arranged at intervals on the backplane circuits respectively, includes: screen-printing the conductive adhesive elements on the backplane circuits, respectively.

In one embodiment, the forming conductive adhesive elements arranged at intervals on the backplane circuits respectively, includes: forming a continuous conductive adhesive layer on the backplane circuits; performing UV curing on areas that cover the connecting ends by a mask; and removing parts that are not subjected to UV curing in the continuous conductive adhesive layer to form the conductive adhesive elements.

In one embodiment, the forming backplane circuits on a flexible substrate includes: forming patterned backplane circuits on the flexible substrate, wherein the patterned backplane circuits include a plurality of island circuits arranged at intervals and a plurality of connecting wires electrically connecting two adjacent island circuits; and forming the connecting ends on the backplane circuits respectively.

In one embodiment, the manufacturing method further includes a step of patterning the flexible substrate, wherein the patterned flexible substrate includes a plurality of island substrates arranged at intervals and a plurality of connecting substrates connecting two adjacent island areas; the island substrates, the island circuits, the conductive adhesive elements and the electronic components are stacked; and the plurality of connecting wires are respectively arranged on the plurality of connecting substrates.

In one embodiment, the manufacturing method further includes a step of forming an upper elastic packaging layer on the electronic components.

In one embodiment, the manufacturing method further includes a step of forming a lower elastic packaging layer on the lower side of the flexible substrate.

Compared with the prior art, the electronic device provided in the embodiments of the present disclosure enables the plurality of electronic components to be respectively electrically connected with the backplane circuits by virtue of the conductive adhesive elements arranged at intervals. Therefore, when the electronic device is stressed by an external force to be in a stretching or deforming state, corresponding deformation occurs in an interval area of two adjacent conductive adhesive elements, while the conductive adhesive elements arranged at intervals may not affect the stretching or deforming effect of the electronic device, thereby greatly increasing the stretching or deforming performance of the electronic device.

### BRIEF DESCRIPTION OF THE DRAWINGS

To more clearly describe the technical solutions in the embodiments of the present disclosure, the drawings required to be used in the embodiments or the prior art will be simply presented below. Apparently, the drawings in the following description are merely some embodiments of the present disclosure, and for those ordinary skilled in the art, other drawings can also be obtained according to these drawings without contributing creative labor.

FIG. 1 is a structural schematic diagram of an electronic device provided by an embodiment of the present disclosure;

FIG. 2 is a structural schematic diagram of a cross-section at line I-I in the electronic device shown in FIG. 1;

FIG. 3 is a flow chart of a method used for manufacturing the electronic device shown in FIG. 1;

FIGS. 4a-4c are corresponding structural schematic diagrams of a manufacturing method of an array substrate shown in FIG. 3;

FIG. 5 is one structural schematic diagram of conductive adhesive elements arranged at intervals formed on backplane circuits;

FIG. 6 is another structural schematic diagram of conductive adhesive elements arranged at intervals formed on backplane circuits;

FIG. 7 is a structural schematic diagram of another electronic device provided by another embodiment of the present disclosure;

FIGS. 8a-8b are flow charts of a method used for manufacturing the electronic device shown in FIG. 7; and

FIGS. 9a-9f are corresponding structural schematic diagrams of the manufacturing method of the electronic device shown in FIGS. 8a-8b.

### DETAILED DESCRIPTION OF THE INVENTION

Technical solutions in the embodiments of the present disclosure are described clearly and fully below in combination with the drawings in the embodiments of the present disclosure. Apparently, the described embodiments are merely part of the embodiments of the present disclosure, not all of the embodiments. Based on the embodiments in the present disclosure, all other embodiments obtained by those ordinary skilled in the art without contributing creative labor will belong to the protection scope of the present disclosure.

The terms “first”, “second”, etc. in the description, claims and drawings of the present disclosure are used to distinguish different objects, not to describe a specific order. In addition, the terms “including” and “having” and any variations thereof are intended to cover non-exclusive inclusions. For example, a process, method, system, product, or device that includes a series of steps or units is not limited to the listed steps or units, but optionally includes unlisted steps or units, or optionally also includes other steps or units inherent to these processes, methods, products or devices.

It should be indicated in the explanation of the present disclosure that, unless otherwise specifically regulated and defined, terms such as “installation”, “connected” and “connection” shall be understood in broad sense. For example, “connection” may refer to fixed connection or detachable connection or integral connection, may refer to mechanical connection, and may refer to direct connection or indirect connection through an intermediate medium or inner communication of two components. For those ordinary skilled in the art, the specific meanings of the above terms in the present disclosure may be understood according to specific conditions. In addition, the terms “including” and “having” and any variations thereof are intended to cover non-exclusive inclusions.

With reserved traditional functions, a flexible electronic device also has a certain flexibility and ductility. Therefore, the flexible electronic device is rapidly developed and widely applied, and particularly has wide application prospects in the fields such as biomedicine, intelligent wearable devices, flexible display, health care and military affairs.

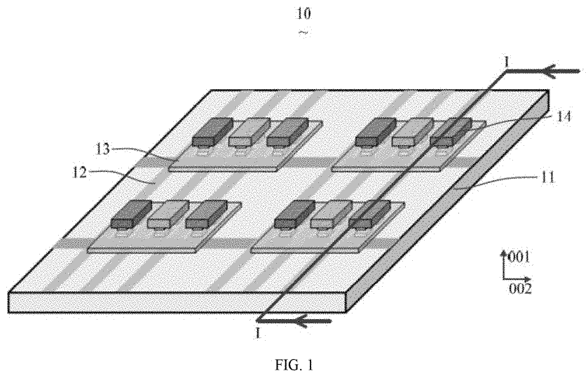

FIG. 1 is a structural schematic diagram of an electronic device provided by an embodiment of the present disclosure. As shown in FIG. 1, the electronic device 10 includes a flexible substrate 11, backplane circuits 12, a plurality of conductive adhesive elements 13 and a plurality of electronic components 14.

The backplane circuits 12 are arranged on the flexible substrate 11; the plurality of conductive adhesive elements 13 are arranged at interval on the backplane circuits 12; at least one of the electronic components 14 is arranged on each of the conductive adhesive elements 13; an interval area is formed between every two adjacent conductive adhesive elements 13; no conductive adhesive element 13 is arranged in the interval area. The flexible substrate 11, the backplane circuits 12, the conductive adhesive elements 13 and the electronic components 14 are stacked along a first direction 001; and the first direction 001 is a thickness direction of the flexible substrate 11. The plurality of electronic components are electrically connected with the backplane circuits 12 through the conductive adhesive elements 13 so as to receive an electrical signal, and work under drive of the electrical signal.

Further, the backplane circuits 12 arranged on the flexible substrate 11 are flexible circuits, while the electronic components 14 arranged on the conductive adhesive elements 13 are rigid components, i.e., an elastic coefficient of the backplane circuits 12 is smaller than that of the electronic components 14. Thus, when the electronic device 10 deforms under the action of an external force, the flexible backplane circuits 12 can deform accordingly, while a poor deformation effect only has small influence on the rigid electronic components 14.

Specifically, the flexible substrate 11 is made of flexible materials; and the flexible materials include but are not limited to low-modulus polydimethylsiloxane, elastic polyimide, polyurethane and elastic materials. Optionally, the substrate 11 may be manufactured by hard materials; and the hard materials include but are not limited to glass, silicon substrates and the like.

Specifically, each of the electronic components 14 includes one or a plurality of Micro-LEDs; and the backplane circuits 12 are TFT circuits and are used for driving the Micro-LEDs in the electronic components 14 to exit light. Optionally, each of the electronic components 14 may include one or a plurality of organic light-emitting diodes (OLEDs), which is not specifically limited in the embodiments of the present disclosure.

The present embodiment has the beneficial effects as follows: during deforming of the electronic device 10 by stretching or bending under the action of the external force, since the conductive adhesive elements 13 are arranged at intervals on the flexible substrate 11, deformations of the electronic device 10, such as stretching or bending, may be realized by virtue of the interval area between every two adjacent conductive adhesive elements 13, without being affected by high rigidity of the cured conductive adhesive elements 13. Therefore, the electronic device 10 has higher deformation performance.

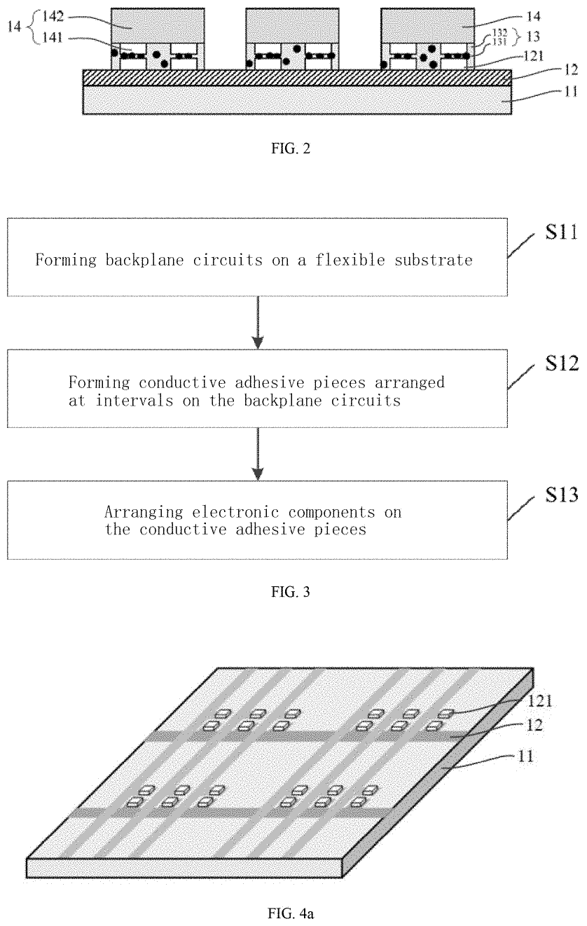

FIG. 2 is a structural schematic diagram of a cross section of line I-I in the electronic device shown in FIG. 1. As shown in FIG. 2, the conductive adhesive elements 13 and the electronic components 14 in stacked connection are arranged at intervals on the flexible substrate 11 covered by the backplane circuits 12. Moreover, conductive ends 141 of the electronic components 14 are electrically connected with connecting ends 121 of the backplane circuits 12 through conductive particles 131 in the conductive adhesive elements 13. Functional components 142 in the electronic components 14 can receive an electrical signal transmitted from the backplane circuits 12, and work according to driving of the electrical signal.

Specifically, the conductive adhesive elements 13 are made from anisotropic conductive materials, include the conductive particles 131 and polymers 132, and are used for realizing vertical conduction and horizontal insulation of electrical signals between the connecting ends 121 of the backplane circuits 12 and the conductive ends 141 of the electronic components 14, wherein the vertical direction is the first direction 001; the horizontal direction is a second direction 002; and the first direction 001 and the second direction 002 are perpendicular to each other. The polymers 132 have adhesive properties and are used for adhering the connecting ends 121 of the backplane circuits 12 and the conductive ends 141 of the electronic components 14. The conductive particles 131 have unilateral conductivity and are used for realizing vertical conduction and horizontal insulation of the electrical signals between the connecting ends 121 of the backplane circuits 12 and the conductive ends 141 of the electronic components 14.

Further, the conductive end 141 in each electronic component 14 includes a first terminal and a second terminal; and the first terminal and the second terminal protrude out of the functional components 142 in the electronic component 14 and face the conductive adhesive elements 13. The connecting end 121 of the backplane circuits 12 that corresponds to each electronic component 14 includes a third terminal and a fourth terminal; and the third terminal and the fourth terminal protrude out of the backplane circuits 12 and face the conductive adhesive elements 13. The first terminal and the third terminal are arranged corresponding to each other and press the conductive adhesive elements 13 together so as to realize electrical connection; and the second terminal and the fourth terminal are arranged corresponding to each other and press the conductive adhesive elements 13 together so as to realize electrical connection.

It can be understood that, the conductive end 141 of the electronic component 14 and/or the connecting end 121 of the backplane circuits 12 form an electrical connector of the electronic device 10, i.e., the first terminal and the second terminal of the conductive end 121 of the electronic component 14 form the electrical connector of the electronic device 10; or, the third terminal and the fourth terminal of the connecting end 121 of the backplane circuits 12 form the electrical connector of the electronic device 10; or, the first terminal and the second terminal of the conductive end 121 of the electronic component 14 and the third terminal and the fourth terminal of the connecting end 121 of the backplane circuits 12 form the electrical connector of the electronic device 10. Specific limitation is not given herein in the embodiments of the present disclosure.

The present embodiment has the beneficial effects as follows: during deforming of electronic device 10 by stretching or bending under the action of the external force, since the conductive adhesive elements 13 are arranged at intervals on the flexible substrate 11, deformations of the electronic device 10, such as stretching or bending, may be realized by virtue of the interval area between every two adjacent conductive adhesive elements 13, without being affected by high rigidity of the cured conductive adhesive elements 13. Therefore, the electronic device 10 has higher deformation performance.

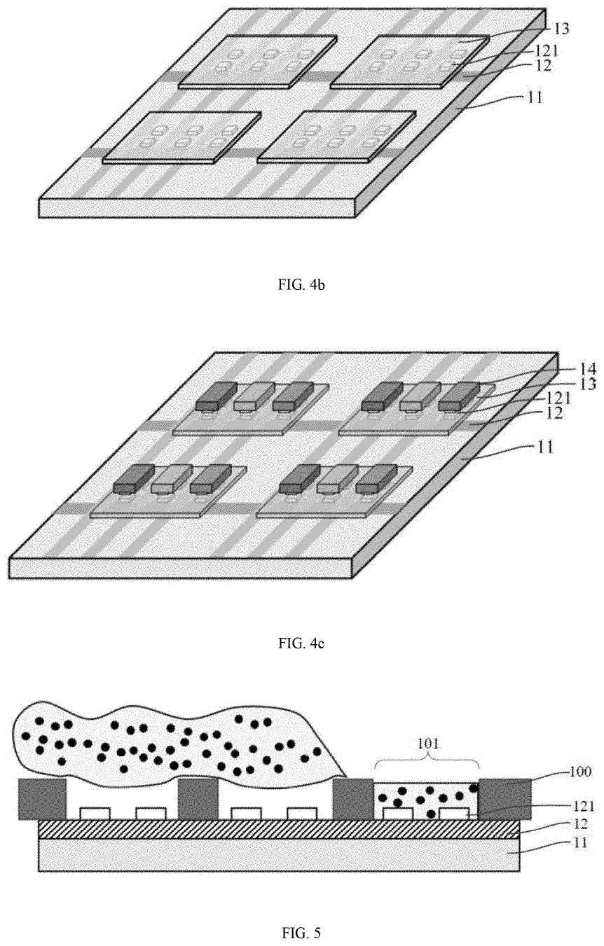

Referring to FIG. 3 and FIGS. 4a-4c, FIG. 3 is a flow chart of a method used for manufacturing the electronic device shown in FIG. 1; and FIGS. 4a-4c are corresponding structural schematic diagrams of a manufacturing method of an array substrate shown in FIG. 3.

S11, backplane circuits are formed on a flexible substrate.

Specifically, as shown in FIG. 4a, the backplane circuits 12 are arranged on the flexible substrate 11; and a plurality of groups of connecting ends 121 at intervals are arranged on the backplane circuits 12.

Further, each group of connecting ends 121 includes three connecting ends 121; and each of the three connecting ends 121 respectively corresponds to one electronic component 14 in three primary colors.

S12, Conductive adhesive elements are arranged at intervals on the backplane circuits.

Specifically, as shown in FIG. 4b, after the backplane circuits 12 including the plurality of connecting ends 121 are formed on the flexible substrate 11, the conductive adhesive elements 13 are arranged at intervals on the backplane circuits 12; and the conductive adhesive elements 13 are anisotropic conductive materials and include conductive particles 131 and polymers 132.

Further, a method for forming conductive adhesive elements 13 arranged at intervals on the backplane circuits 12 includes:

As shown in FIG. 5, the conductive adhesive elements 13 are screen-printed on the backplane circuits 12, i.e., a mask 100 is arranged on the flexible substrate 11; the conductive adhesive elements 13 are printed in a hollow area 101 of the mask 100; then, the mask 100 is removed; and thus, the conductive adhesive elements 13 are arranged at intervals on the backplane circuits 12.

Optionally, the method for forming conductive adhesive elements 13 arranged at intervals on the backplane circuits 12 includes:

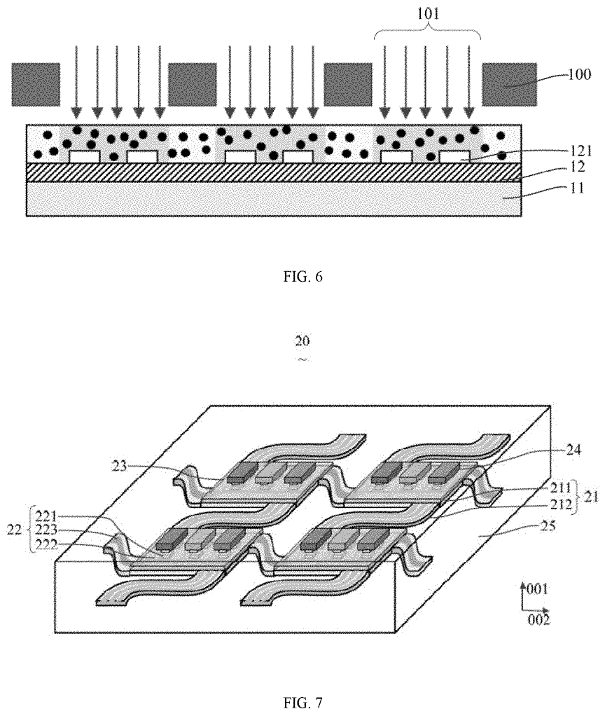

As shown in FIG. 6, firstly, continuous conductive adhesive elements 13 of a whole surface are formed on the backplane circuits 12; secondly, the conductive adhesive elements 13 are subjected to ultraviolet curing through the hollow area 101 of the mask 100; and finally, partial conductive adhesive elements 13 that are not subjected to UV (Ultraviolet Rays) curing in the continuous conductive adhesive elements are removed, and the mask 100 is removed, so as to obtain the conductive adhesive elements 13 arranged at intervals on the backplane circuits 12.

S13, Electronic components are arranged on the conductive adhesive elements.

Specifically, as shown in FIG. 4c, after the conductive adhesive elements 13 are arranged at intervals on the backplane circuits 12, the electronic components 14 are arranged on the conductive adhesive elements 13. After being pressed by external force, the conductive end 141 of each electronic component 14 can be electrically connected with the corresponding connecting end 121 of the backplane circuits 12 through the conductive particles 131 in the conductive adhesive elements 13. Therefore, an electrical signal output by the backplane circuits 12 can be transmitted to the electronic component 14, so that functional components 142 of the electronic components 14 work.

The present embodiment has the beneficial effects as follows: during deforming of electronic device 10 by stretching or bending under the action of the external force, since the conductive adhesive elements 13 are arranged at intervals on the flexible substrate 11, deformations of the electronic device 10, such as stretching or bending, may be realized by virtue of the interval area between every two adjacent conductive adhesive elements 13, without being affected by high rigidity of the cured conductive adhesive elements 13. Therefore, the electronic device 10 has higher excellent deformation performance.

Further, as shown in FIG. 5 or FIG. 6, the method for forming the conductive adhesive elements 13 arranged at intervals on the backplane circuits 12 is fast and accurate. In addition, the conductive adhesive elements 13 arranged at intervals may be formed on the backplane circuits 12 by virtue of any other manufacturing method with the same effect, while the method is not limited to the method shown as FIG. 5 or FIG. 6. Specific limitation is not given herein in the embodiments of the present disclosure.

FIG. 7 is a structural schematic diagram of another electronic device provided by the another embodiment of the present disclosure. As shown in FIG. 7, an electronic device 20 includes a flexible substrate 21, backplane circuits 22, a plurality of conductive adhesive elements 23, a plurality of electronic components 24 and an elastic packaging layer 25.

The flexible substrate 21 is patterned by etching as a whole, i.e., only island substrates 211 arranged at intervals and a plurality of connecting substrates 212 used for connecting two adjacent island substrates are reserved on the flexible substrate 21.

Specifically, the patterned backplane circuits 22 are arranged on the flexible substrate 21, i.e., the patterned backplane circuits include island circuits 222 arranged at intervals and a plurality of connecting wires 223 used for electrically connecting two adjacent island circuits 222; the connecting wires 223 are arranged on the connecting substrates 212; the island circuits 222 are arranged on the island substrates 211; and a plurality of connecting ends 221 are arranged on the upper surfaces of the island circuits.

Further, the plurality of conductive adhesive elements 23 are respectively arranged on the plurality of island circuits 222; and at least one electronic component 24 is arranged on each of the conductive adhesive elements 23. The island substrates 211, the island circuits 222, the conductive adhesive elements 23 and the electronic components 24 are stacked along the first direction 001; and the first direction 001 is a thickness direction of the flexible substrate 21. The plurality of electronic components are electrically connected with the backplane circuits 22 through the conductive adhesive elements 23 so as to receive an electrical signal, and work under driving of the electrical signal.

Specifically, the elastic packaging layer 25 includes an upper elastic packaging layer and a lower elastic packaging layer. The upper elastic packaging layer is used for enclosing an upper surface of the flexible substrate 21; the lower elastic packaging layer is arranged on a lower surface of the flexible substrate 21, i.e., a stacked structure composed of the flexible substrate 21, the backplane circuits 22, the plurality of conductive adhesive elements 23 and the plurality of electronic components 24 is completely enclosed in the elastic packaging layer 25. Optionally, the elastic packaging layer 25 may include the upper elastic packaging layer or the lower elastic packaging layer only, i.e., only the upper elastic packaging layer is used for enclosing the upper surface of the flexible substrate 21, or only the lower elastic packaging layer is arranged on the lower surface of the flexible substrate 21. Specific limitation is not given herein in the embodiments of the present disclosure.

Further, the backplane circuits 22 arranged on the flexible substrate 21 are flexible circuits, while the electronic components 24 arranged on the conductive adhesive elements 23 are rigid components, i.e., an elastic coefficient of the backplane circuits 22 are smaller than that of the electronic components 24. Thus, when the electronic device 20 deforms under the action of an external force, the flexible backplane circuits 22 can deform accordingly, while a poor deformation effect only has small influence on the rigid electronic components 24.

Specifically, the flexible substrate 21 is made of flexible materials; and the flexible materials include but are not limited to low-modulus polydimethylsiloxane, elastic polyimide, polyurethane and elastic materials. Optionally, the substrate 21 may be manufactured by hard materials; and the hard materials include but are not limited to glass, silicon substrates and the like.

Specifically, each of the electronic components 24 includes one or a plurality of Micro-LEDs; and the backplane circuits 22 are TFT circuits and are used for driving the Micro-LEDs in the electronic components 24 to exit light. Optionally, each of the electronic components 24 may include one or a plurality of organic light-emitting diodes (OLEDs), which is not specifically limited in the embodiments of the present disclosure.

The present embodiment has the beneficial effects as follows: during deforming of electronic device 20 by stretching or bending under the action of the external force, since the conductive adhesive elements 23 are arranged at intervals on the flexible substrate 21, deformations of the electronic device 20, such as stretching or bending, may be realized by virtue of the interval area between every two adjacent conductive adhesive elements 23, without being affected by high rigidity of the cured conductive adhesive elements 23. Therefore, the electronic device 20 has higher excellent deformation performance.

Further, when the electronic device 20 works, since the connecting wires 223 on the connecting substrates 212 are patterned the connecting wires 223 can also change along with deformations of the connecting substrates 212; and thus, the poor stretching force hardly can directly act on the electronic components 24. Therefore, the electronic device 20 can also normally work in a stretching state, thereby further increasing the deformation performance of the electronic device 20.

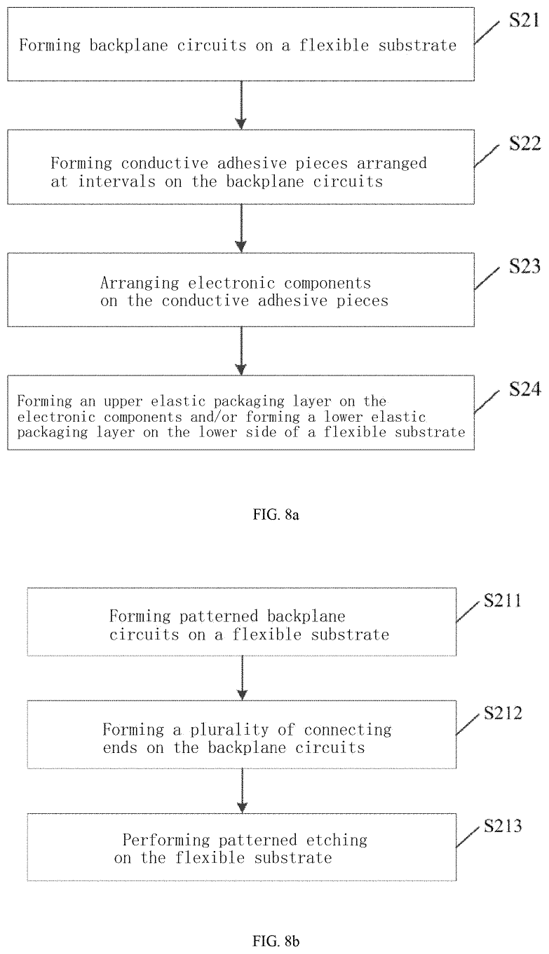

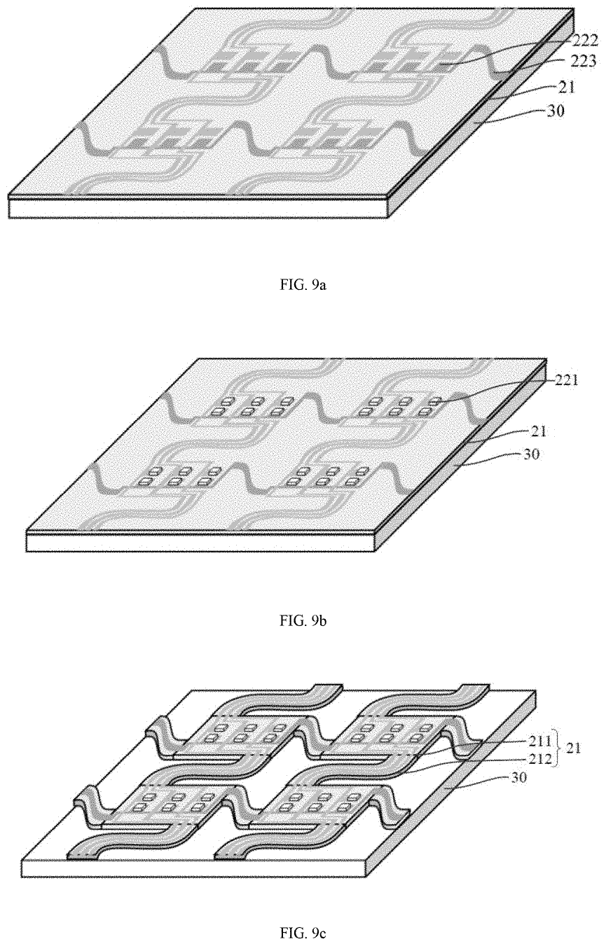

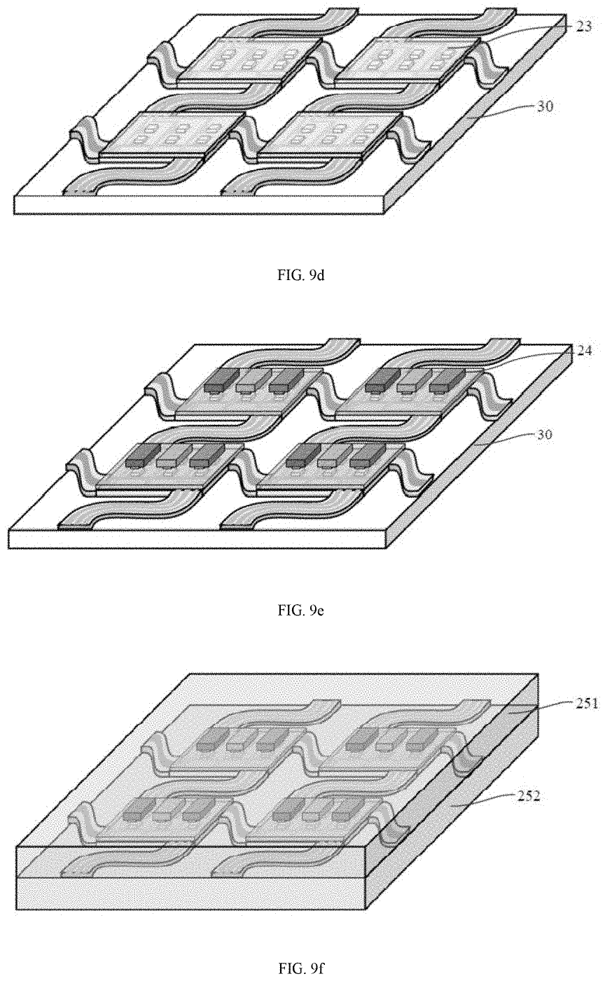

Referring to FIGS. 8a-8b and FIGS. 9a-9f, FIGS. 8a-8b are flow charts of a method used for manufacturing the electronic device shown in FIG. 7; and FIGS. 9a-9f are corresponding structural schematic diagrams of the manufacturing method of the electronic device shown in FIGS. 8a-8b.

S21, backplane circuits are formed on a flexible substrate.

Specifically, the backplane circuits 22 are arranged on the flexible substrate 21; and a plurality of groups of connecting ends 221 at intervals are arranged on each island circuit 222 of the backplane circuits 22.

Specifically, the lower surface of the flexible substrate 21 is connected with a rigid substrate 30; rigidity of the rigid substrate 30 is higher than that of the flexible substrate 21 made of an elastic material; and the rigid substrate 30 is used for providing a rigid supporting surface for the flexible substrate 21, thereby facilitating a subsequent patterned etching on the flexible substrate 21.

Further, the step that the backplane circuits 22 are formed on the flexible substrate 21 includes as follows:

S211, patterned backplane circuits are formed on the flexible substrate.

Specifically, as shown in FIG. 9a, the patterned backplane circuits 22 are arranged on the flexible substrate 21 with a whole surface. The backplane circuits 22 include island circuits 222 and connecting circuits 223, i.e., the patterned backplane circuits 22 include the island circuits 222 arranged at intervals and a plurality of connecting wires 223 used for electrically connecting two adjacent island circuits 222.

S212, A plurality of connecting ends are formed on the backplane circuits.

Specifically, as shown in FIG. 9b, after the patterned backplane circuits 22 are formed on the flexible substrate 21 with the whole surface, a plurality of groups of connecting ends 221 are arranged on each island circuit 222 of the backplane circuits 22. Each group of connecting ends 221 includes three connecting ends 221; and each of the three connecting ends 221 respectively corresponds to one electronic component 24 in three primary colors.

S213, the flexible substrate is patterned by etching.

Specifically, as shown in FIG. 9c, after the plurality of groups of connecting ends 221 are arranged on each island circuit 222, the flexible substrate 21 with the whole surface patterned by etching, so that island substrates 211 arranged at intervals and a plurality of connecting substrates 212 used for connecting two adjacent island substrates are reserved on the flexible substrate 21. The connecting wires 223 are arranged on the connecting substrates 212; the island circuits 222 are arranged on the island substrates 211; and the plurality of connecting ends 221 are arranged on the upper surfaces of the island circuits.

S22, Conductive adhesive elements are arranged at intervals on the backplane circuits.

Specifically, as shown in FIG. 9d, after the backplane circuits 22 including the plurality of connecting ends 221 are formed on the flexible substrate 21, the conductive adhesive elements 13 are arranged at intervals on the backplane circuits 22; and the conductive adhesive elements 13 are anisotropic conductive materials and include conductive particles and polymers.

Further, the conductive adhesive elements 23 arranged at intervals may be formed on the backplane circuits 22 by virtue of the method shown in FIG. 5 or FIG. 6. Specific limitation is not given herein in the embodiments of the present disclosure.

S23, Electronic components are arranged on the conductive adhesive elements.

Specifically, as shown in FIG. 9e, after the conductive adhesive elements 23 are arranged at intervals on the backplane circuits 22, the electronic components 24 are arranged on the conductive adhesive elements 23. After being pressed, the conductive end of each electronic component 24 can be electrically connected with the corresponding connecting end 221 on the backplane circuits 22 through the conductive particles in the conductive adhesive elements 23. Therefore, an electrical signal output by the backplane circuits 22 can be transmitted to the electronic component 24, so that functional components in the electronic components 24 work.

S24, An upper elastic packaging layer is formed on the electronic components and/or a lower elastic packaging layer is formed on the lower side of the flexible substrate.

Specifically, as shown in FIG. 9f, after the electronic components 24 are arranged on the conductive adhesive elements 23, an upper elastic packaging layer 251 is formed on the electronic components 24; then, the rigid substrate 30 connected with the lower surface of the flexible substrate 21 is removed; and a lower elastic packaging layer 252 is formed on the lower side of the flexible substrate 23, i.e., the upper elastic packaging layer 251 and the lower elastic packaging layer 252 form an elastic packaging layer 25; and a stacked structure composed of the flexible substrate 21, the backplane circuits 22, the plurality of conductive adhesive elements 23 and the plurality of electronic components 24 is completely enclosed in the elastic packaging layer 25.

Optionally, the elastic packaging layer 25 may include the upper elastic packaging layer 251 or the lower elastic packaging layer 252 only, i.e., only the upper elastic packaging layer 251 is used for enclosing the upper surface of the flexible substrate 21, or only the lower elastic packaging layer 252 is arranged on the lower surface of the flexible substrate 21. Specific limitation is not given herein in the embodiments of the present disclosure.

The present embodiment has the beneficial effects as follows: through the methods shown in FIGS. 8a-8b, the electronic device 20 shown in FIG. 7 may be obtained. When the electronic device 20 is in a stretching state under the external force, the connecting substrates 212 of the flexible substrate 21 and the connecting wires 223 arranged on the connecting substrates 212 deform accordingly, while the island substrates 211, the island circuits 222, the conductive adhesive elements 23 and the electronic components 24 stacked together may be less affected by the poor stretching stress. Meanwhile, the structure of the electronic device 20 can also be stabilized and protected by virtue of the elastic packaging layer 25, thereby increasing the deformation performance of the electronic device 20.

Compared with the related art, the electronic device provided in the embodiments of the present disclosure enables the plurality of electronic components to be respectively electrically connected with the backplane circuits by virtue of the conductive adhesive elements arranged at intervals. Therefore, when the electronic device is subjected to the external force in a stretching or deforming state, corresponding deformation occurs in an interval area of two adjacent conductive adhesive elements, while the conductive adhesive elements arranged at intervals may not affect the stretching or deforming effect of the electronic device, thereby greatly increasing the stretching or deforming performance of the electronic device.

In the illustration of this description, the illustration of reference terms “one embodiment”, “some embodiments”, “example”, “specific example” or “some examples”, etc. means that specific features, structures, materials or characteristics illustrated in combination with the embodiment or example are included in at least one embodiment or example of the present disclosure. In this description, exemplary statements for the above terms do not must aim at the same embodiment or example. Moreover, the described specific features, structures, materials or characteristics can be combined appropriately in any one or more embodiments or examples.

The above describes the array substrate and the manufacturing method thereof provided by the embodiments of the present disclosure in detail. Specific examples are used herein to illustrate the principles and implementations of the present disclosure. The descriptions of the above embodiments are only used to help to understand the method and core idea of the present disclosure. At the same time, for those ordinary skilled in the art, according to the idea of the present disclosure, the detailed description and the scope of disclosure may be changed. In conclusion, the content of this description shall not be construed as a limitation to the present disclosure.

1. An electronic device, comprising:
a plurality of backplane circuits;
a plurality of conductive adhesive elements arranged on the backplane circuits at intervals, respectively; and
a plurality of electronic components arranged on the plurality of conductive adhesive elements respectively,
wherein the backplane circuits are respectively electrically connected with the plurality of electronic components through the plurality of conductive adhesive elements.

2. The electronic device according to claim 1, wherein the backplane circuits are flexible; and the electronic components are rigid.

3. The electronic device according to claim 1, further comprising an electrical connector arranged on each of the backplane circuits or the electronic components, wherein the conductive adhesive elements are anisotropic conductive materials; and the conductive adhesive elements are pressed by the electrical connector to realize vertical conduction and horizontal insulation between the backplane circuits and the electronic components.

4. The electronic device according to claim 3, wherein the electrical connector comprises a first terminal and a second terminal arranged on each electronic component; and the first terminal and the second terminal protrude out of the electronic component and face a corresponding conductive adhesive element.

5. The electronic device according to claim 3, wherein the electrical connector comprises a third terminal and a fourth terminal arranged on each of the backplane circuits; and the third terminal and the fourth terminal protrude out of the backplane circuit and face a corresponding conductive adhesive element.

6. The electronic device according to claim 3, wherein the electrical connector comprises a first terminal and a second terminal arranged on each of the electronic components, and a third terminal and a fourth terminal arranged on each of the backplane circuits;
the first terminal and the second terminal protrude out of the electronic component and face a corresponding conductive adhesive element; the third terminal and the fourth terminal protrude out of the backplane circuit and face a corresponding conductive adhesive element; and
the first terminal and the third terminal are arranged opposite to each other and press a corresponding conductive adhesive element together so as to realize electrical connection between the backplane circuit and the electronic component; and the second terminal and the fourth terminal are arranged opposite to each other and press a corresponding conductive adhesive element together so as to realize electrical connection between the backplane circuit and the electronic component.

7. The electronic device according to claim 2, further comprising a flexible substrate arranged on one side of the backplane circuits away from the conductive adhesive elements.

8. The electronic device according to claim 7, wherein
the flexible substrate comprises a plurality of island substrates arranged at intervals and a plurality of connecting substrates connecting two adjacent island substrates;
the backplane circuits comprise a plurality of island circuits arranged at intervals and a plurality of connecting wires electrically connecting two adjacent island circuits;
the island substrates, the island circuits, the conductive adhesive elements and the electronic components are stacked; and
the plurality of connecting wires are respectively arranged on the plurality of connecting substrates.

9. The electronic device according to claim 4, wherein each of the electronic components comprise one or a plurality of Micro-LEDs; the first terminal and the second terminal are respectively a cathode and an anode of the Micro-LED; the backplane circuits are TFT circuits; and the TFT circuits are electrically connected with the Micro-LEDs and drive the Micro-LEDs through the third terminals and the fourth terminals.

10. The electronic device according to claim 7, further comprising an upper elastic packaging layer enclosing the electronic components or a lower elastic packaging layer arranged on a lower side of the flexible substrate.

11. A manufacturing method of an electronic device, comprising:
forming a plurality of backplane circuits on a flexible substrate, wherein the backplane circuits have a plurality of connecting ends formed thereon respectively;
forming conductive adhesive elements arranged at intervals on the backplane circuits respectively, wherein the conductive adhesive elements are anisotropic conductive materials; and
arranging electronic components on the conductive adhesive elements respectively, wherein the electronic components have a plurality of conductive ends formed thereon respectively;
the conductive ends and the connecting ends are arranged opposite to each other and press the conductive adhesive elements together so as to realize electrical connection between the backplane circuits and the electronic components.

12. The method according to claim 11, wherein the forming conductive adhesive elements arranged at intervals on the backplane circuits respectively, comprises:
screen-printing the conductive adhesive elements on the backplane circuits, respectively.

13. The method according to claim 11, wherein the forming conductive adhesive elements arranged at intervals on the backplane circuits respectively, comprises:
forming a continuous conductive adhesive layer on the backplane circuits;
performing UV curing on areas that cover the connecting ends by a mask; and
removing parts that are not subjected to UV curing in the continuous conductive adhesive layer to form the conductive adhesive elements.

14. The method according to claim 11, wherein the forming backplane circuits on a flexible substrate comprises:
forming patterned backplane circuits on the flexible substrate, wherein the patterned backplane circuits comprise a plurality of island circuits arranged at intervals and a plurality of connecting wires electrically connecting two adjacent island circuits; and
forming the connecting ends on the backplane circuits respectively.

15. The method according to claim 14, further comprising:
patterning the flexible substrate, wherein the patterned flexible substrate comprises a plurality of island substrates arranged at intervals and a plurality of connecting substrates connecting two adjacent island areas; the island substrates, the island circuits, the conductive adhesive elements and the electronic components are stacked; and the plurality of connecting wires are respectively arranged on the plurality of connecting substrates.

16. The method according to claim 11, further comprising forming an upper elastic packaging layer on the electronic components.

17. The method according to claim 11, further comprising forming a lower elastic packaging layer on a lower side of the flexible substrate.
